(19) United States
(12) Patent Application Publication
(10) Pub. No.: US 2011/0070666 A1
(43) Pub. Date: Mar. 24, 2011

(54) DEPOSITION METHOD

(75) Inventors: Namwoong Paik, Princeton, NJ (US); Jeffrey Joerg, Poughkeepsie, NJ (US)

(73) Assignee: NXP B.V., Eindhoven (NL)

(21) Appl. No.: 12/994,124

(22) PCT Filed: May 22, 2009
(86) PCT No.: PCT/IB2009/052144

§ 371 Date: Dec. 1, 2010

Related U.S. Application Data
(60) Provisional application No. 61/055,282, filed on May 22, 2008.

(51) Int. Cl. H01L 21/66

(52) U.S. Cl. 438/7; 118/694; 257/E21.529

(57) ABSTRACT

Gas phase nucleation conditions are controlled and/or mitigated during material deposition in semiconductor manufacturing processes. According to an example embodiment of the present invention, reaction by-product gases are monitored (e.g., 140, 160) and used to detect reactant gas conditions that promote gas phase nucleation. In some applications, an optical detection approach (e.g., 140, 142) is used to detect the presence of the reaction by-product gases, and relative amounts of the gases are used as an indicator of a ratio of reactant gases (e.g., 310, 340); the supply of reactant gases and/or other deposition conditions are correspondingly controlled (e.g., 130-138, via 160).

This patent document relates to semiconductor device manufacturing, and more particularly, to the formation of semiconductor device materials using reaction gases.

Semiconductor device manufacturers employ a variety of material fabrication techniques for many different applications. Some material fabrication techniques involve the use of a deposition-type approach to form layers or other arrangements of semiconductor material, insulative material, conductive material or other material that is used in a semiconductor wafer. These approaches are desirably controlled with a high degree of reliability to ensure the accuracy, effectiveness and robustness of the manufacturing process.

Tungsten Metallization is a popular method for creating interconnections between device layers formed in a semiconductor manufacturing process. Among various types of tungsten metallization technologies, CVD (Chemical Vapor Deposition) is a popular approach, often employing WF₆, SiH₄, H₂ and Ar in multiple steps to achieve the desired interconnect. Tungsten deposition by CVD using WF₆ can be divided into two stages, nucleation and film growth, which can be helpful for inhibiting or preventing undesirable chemical reactions between reaction gases during the nucleation stage. For instance, gas phase nucleation occurs as a reaction of SiH₄ and WF₆ when the ratio of SiH₄ to WF₆ is greater than 1, producing a large number of WₓSi_{y} particles, which result in contact resistance failure by blocking via holes and increasing film resistivity. In some applications, a TiF₃ layer is formed by interactions between Fluorine and exposed Titanium when a Ti/TiN layer is used as a barrier layer. The TiN can separate from this formed TiF₃ layer and roll up, creating a mound upon further deposition. In many cases, the failure happens within split seconds and it is very difficult to detect.

In order to achieve a highly reliable process, the introduction timing, mixture, and amount of reaction and other gases used in the CVD process are desirably controlled very precisely. However, such precise control has been difficult to achieve; without adequate control, device manufacturing is susceptible to a variety of failure mechanisms. These and other issues have been a source of difficulty in the manufacture of semiconductor devices.

The present invention is directed to overcoming the above-mentioned challenges and others related to the types of applications discussed above and in other applications. These and other aspects of the present invention are exemplified in a number of illustrated implementations and applications, some of which are shown in the figures and characterized in the claims section that follows.

According to an example embodiment of the present invention, reactant gases are introduced to a substrate and the gases are reacted to form metal on the substrate. By-product gases created by reactions between the reactant gases are monitored, and the introduction of reactant gases to the substrate is controlled as a function of the detected by-product gases to mitigate gas phase nucleation. In some applications, the mitigation of gas phase nucleation is effected to control reactions with underlying metal layers in the substrate.

According to another example embodiment of the present invention, a system for nucleation-controlled semiconductor device manufacture includes a gas supply arrangement, an optical detector and a controller. The gas supply arrangement introduces reactant gases to a substrate for reacting the gases to form metal on the substrate. The optical detector arrangement optically detects by-product gases created by reactions between the reactant gases and provides a signal indicative of the detected gases. A controller controls the gas supply arrangement to introduce reactant gases to the substrate as a function of the detected by-product gas signal to mitigate gas phase nucleation.

In another example embodiment of the present invention, the nucleation-controlled growth of a Tungsten layer on a Ti/TiN substrate is carried out as follows. Using a gas flow controller, WF₆ and SiH₄ reactant gases are introduced to a substrate having a TiN barrier layer on a Titanium layer, and the reactant gases are reacted to form a Tungsten seed layer on the TiN barrier layer. While reacting the reactant gases, by-product gases created by reactions between the reactant gases are detected and an output indicative of an intensity of the detected gases is provided. Using the intensity output, feedback control is provided to the gas flow controller to control the introduction of the reactant gases to the substrate to mitigate gas phase nucleation, and to mitigate reactions between WF₆ and the Titanium that form TiF₃.

The above summary is not intended to describe each illustrated embodiment or every implementation of the present invention. The figures and detailed description that follow more particularly exemplify these embodiments.

The invention may be more completely understood in consideration of the following detailed description of various embodiments of the invention in connection with the accompanying drawings, in which:

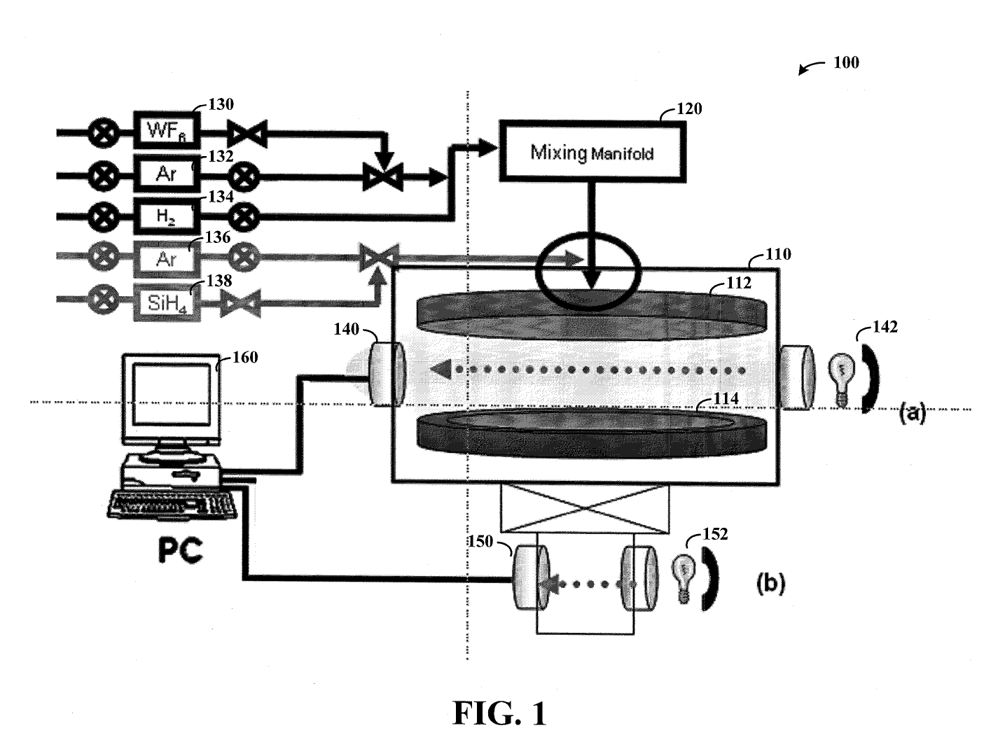

FIG. 1 shows a system for nucleation-controlled semiconductor wafer manufacture, according to an example embodiment of the present invention;

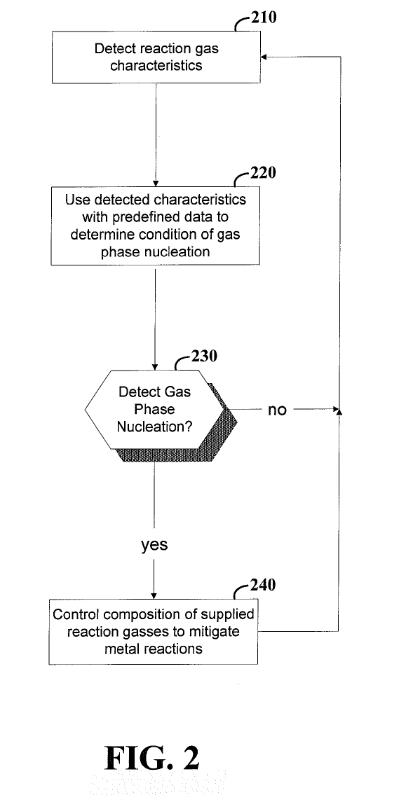

FIG. 2 is a flow diagram for nucleation-controlled semiconductor wafer manufacture, according to another example embodiment of the present invention;

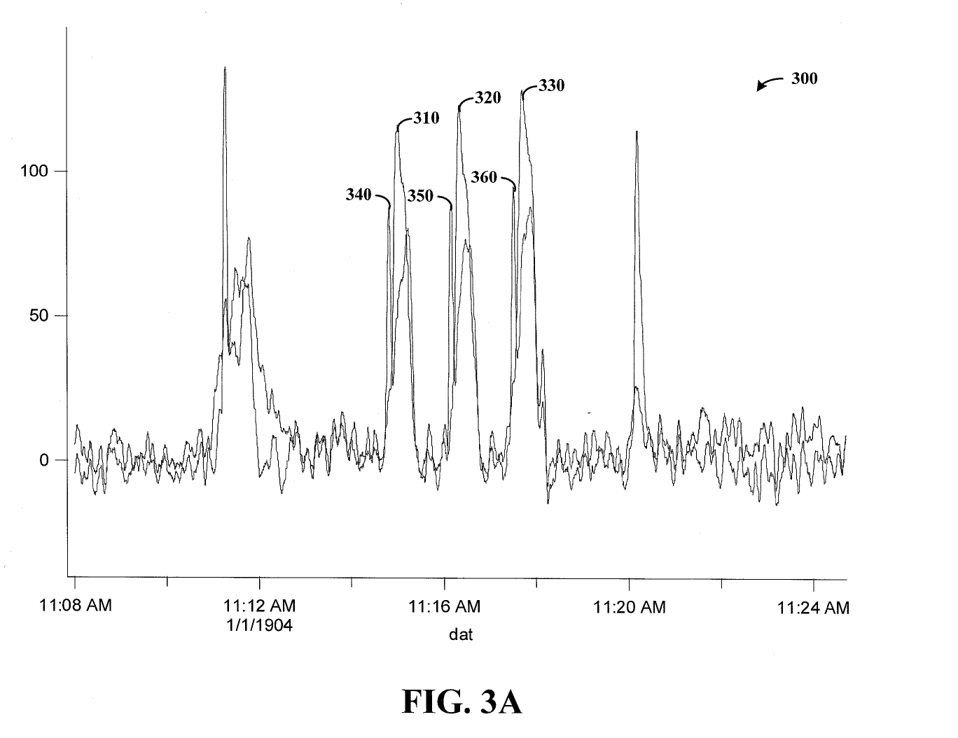

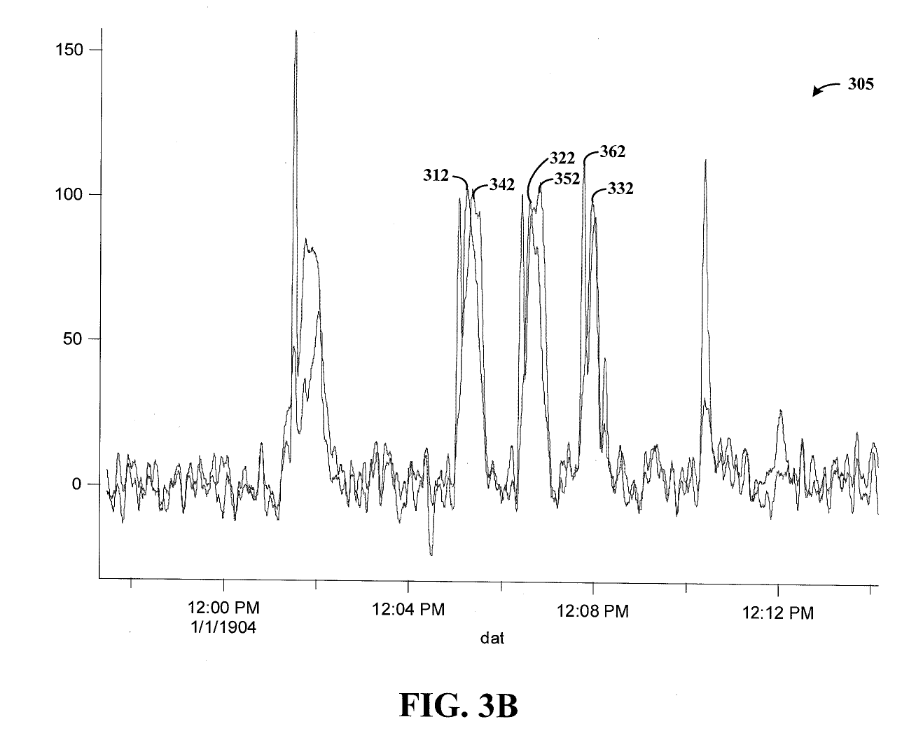

FIG. 3A and FIG. 3B show plots of reaction gas characteristics used to detect gas phase nucleation and control material deposition in accordance with one or more example embodiments of the present invention; and

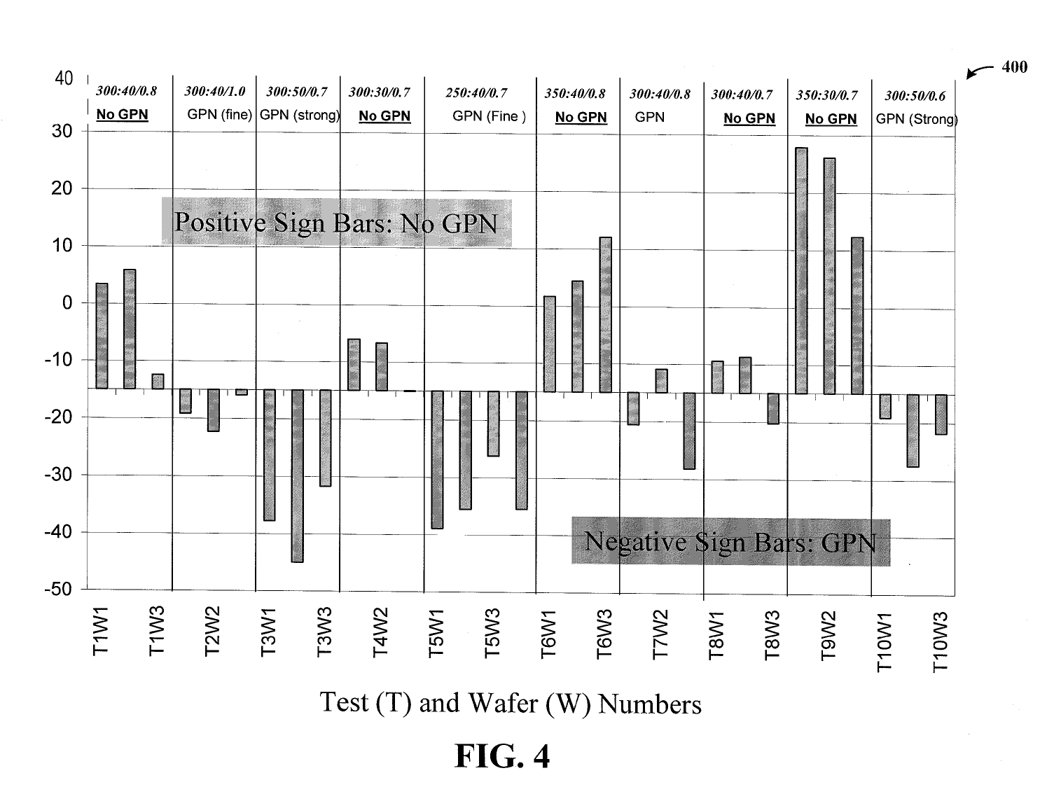

FIG. 4 shows a graphical approach to detecting gas phase nucleation, according to another example embodiment of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the scope of the invention, including that defined by the claims.

The present invention is applicable to a variety of sensor arrangements and approaches, and particularly to the control of gas phase nucleation in the manufacture of semiconductor devices. While the present invention is not necessarily limited to such applications, an appreciation of various aspects of the invention is best gained through a discussion of examples in such an environment.

According to an example embodiment of the present invention, chemical deposition is controlled using detected reaction gas characteristics to determine conditions of deposition relating to gas phase nucleation. The deposition process is controlled relative to the gas phase nucleation, to promote desirable material growth. In some applications, the reaction gases are detected and used as an indicator of a ratio of reactant gases, and the reactant gas supply is controlled to maintain the ratio below a threshold ratio known to promote gas phase nucleation.

In another example embodiment, reaction gas characteristics relating to one or both of reactant gases and products of reaction are optically detected. These characteristics include, for example, the detection of reaction gases and their concentrations, which can be used to determine conditions of the deposition, such as those relating to the relative amounts of reactant gases supplied to the process. The optically-detected characteristics are processed to detect conditions that are favorable to gas phase nucleation. In response to the detection of gas phase nucleation, the deposition process is controlled to mitigate, eliminate or otherwise avoid undesirable chamber conditions such as those involving Titanium attack. For instance, the supply of gas can be altered to mitigate gas phase nucleation, or a subsequent deposition process can be delayed until gas phase nucleation has stopped.

Another example embodiment is directed to the control of gas phase nucleation during a first stage of a two-stage (nucleation and film growth) Tungsten chemical vapor deposition (CVD) process, using a material such as WF₆ and employing a TiN film on an underlying Titanium film as a barrier and adhesion-improving layer for Tungsten. During the first (nucleation) stage, a seed layer is deposited using a material such as SiH₄ to reduce WF₆ and to mitigate or prevent reactions between Fluorine and oxide or substrate (Silicon) in areas where they may not be fully protected with a TiN barrier material, as in the following example:

2.WF₆+3SiH₄=2W+3SiF₄+6H₂@425C, 40 Torr (1)

The flow of SiH₄ and the corresponding reduction of WF₆ is monitored and controlled to mitigate attack upon exposed Titanium below the TiN barrier layer, and to thus mitigate the formation of a TiF₃ layer that can exhibit high resistivity and that is susceptible to delamination. To monitor the reaction, optical spectrometry is used to detect characteristics of reaction gases and by-product gases of the deposition process. The detected characteristics are used to control the introduction timing, mixture, and amount of SiH₄ gas supplied to the CVD process (e.g., SiH₄) in accordance with a relationship between gas dynamics and gas phase nucleation, to achieve a highly reliable process and mitigate gas phase nucleation.

In many applications, the ratio of SiH₄ to WF₆ is monitored via optical spectrometry-based detection of one or more related reaction gas byproducts (i.e., SiF₄ and WF₆), and the gas supply during the nucleation/seed layer deposition stage is controlled to ensure that the ratio is less than about 1. The control is effected to ensure that WₓSi_{y} particles are not produced in great number (or at all), to mitigate or eliminate undesirable conditions that may result in contact resistance failure when such particles block via holes and/or increase film resistivity.

After the first (nucleation) stage, a subsequent Tungsten layer is deposited (e.g., with H₂ reduction), such as characterized in the following Equation 2:

WF₆+3H₂=W+6HF@425C, 40 Torr (2)

With this approach, desirable Tungsten formation is achieved with a Ti/TiN barrier layer in a manner that mitigates or avoids Titanium attack.

Turning now to the figures, FIG. 1 shows a system 100 for nucleation-controlled semiconductor wafer manufacture, according to another example embodiment of the present invention. The system 100 includes a deposition chamber 110 to which gas is supplied by a mixing manifold 120, which draws from several gas sources 130, 132, 134, 136 and 138. The shown gases WF₆, Ar, H₂ and SiH₄ are exemplary, as is their application to a deposition process involving the formation of a Tungsten layer upon a Ti/TiN layer. Detectors 140 and 150 are coupled with the deposition chamber 110 to detect gas conditions therein. A computer 160 is connected to the detectors 140 and 150 for receiving signals therefrom, and is programmed to process the signals for determining characteristics of deposition processes carried out in the deposition chamber 110.

The detectors 140 and 150 form part of separate infrared (IR) spectrometers that respectively include IR sources 142 and 152. The spectrometer 140/142 detects gas characteristics across the deposition chamber 110, and the spectrometer 150/152 detects gas characteristics across the fore-line pumping line of the deposition chamber. These sources generate infrared light that is passed through a portion of the deposition chamber 110 and detected to provide an indication of gas phase nucleation in the deposition chamber. The source 142 passes light to the detector 140 between upper and lower platens 112 and 114, which apply an electric field to carry out the deposition process upon a wafer placed between the platens. The source 152 passes IR light to the detectors 150 through an extension of the deposition chamber 110. Generally, the detected IR light provides an indication of the gaseous materials through which the light passes.

The type, number and placement of IR spectrometers varies depending upon the application, available location or convenience. For instance, while two IR spectrometers are shown, certain embodiments involve the use of only one of the shown spectrometers, and other embodiments involve the use of additional spectrometers that may be similar to those shown, or other types of detectors. The IR spectrometers can also be installed in other locations where process gas flows or is otherwise present, and where a clear optical path exists between a light source unit and a detection unit.

In one embodiment, the spectrometers 140/142 and 150/152 are 4-channel IR spectrometers that monitor and record intensity relating to four different gas species. Each channel is configured to a pre-set wavelength so as to provide a response that is specific to a particular gas. An intensity-based output from each channel is provided to the computer 160, which uses the intensity to determine an amount of each particular gas (relative or otherwise), and correspondingly to determine conditions of deposition relating to the particular gas.

Deposition characteristics determined by the computer 160 are used in one or more manners in order to control aspects of the deposition process. In one embodiment, the computer 160 is coupled to provide a control signal for controlling the amount of respective gases (130-138) supplied to the deposition chamber 110, and effects that control to set desirable supply gas ratios.

In some embodiments, the computer 160 is programmed to mitigate Titanium attack, such as described above, by using the output from one or both of the IR spectrometers 140/142 and 150/152 to monitor Silane gas in deposition processes. The computer 160 executes data interpretation software to interpret the signal and determine whether conditions favorable to gas phase nucleation are present. When these conditions are detected, the computer 160 uses a feedback-control-loop approach to control the composition of gas in the deposition chamber 110 by controlling the gas supplied to the chamber, thus controlling the deposition process to mitigate or avoid Titanium attack (i.e., the reaction of Titanium with gases to form a material that has undesirable characteristics).

In some embodiments, tests are carried out using a system such as that shown in FIG. 1 to determine flow rates, valve delays and/or other conditions relating to deposition gas supply that result in the occurrence of gas phase nucleation (and corresponding undesirable attack/reaction with device materials). The results of these tests are used to set parameters that are used by a computer, together with data characterizing deposition chamber characteristics, to control deposition processes in the chamber.

In another embodiment, reaction gases are detected in a control environment that is operated in parallel with a deposition chamber, and conditions detected in the control environment are used to control the operation of the deposition chamber. The control environment is separate from the deposition chamber, but operated with gas flow control and other characteristics that are similar to those in the deposition chamber. For instance, the control environment may be a chamber similar to the chamber shown in FIG. 1 as used for deposition, with like-controlled gas supply and other conditions as appropriate.

The following table shows example results for such a testing approach with different process conditions that may be carried out and/or used in connection with one or more example embodiments. The intensity of gas phase can be quantified by the signal strength of detected IR radiation via IR spectrometry using an approach such as that described above.

| | VALVE | SiH₄ | WF₆ | IR | |
|---|---|---|---|---|---|
| RUN | DELAY | FLOW | FLOW | detection | VISUAL RESULT |
| 1 | 1.4 | 40 | 300 | 0 | No GPN Observed |
| 2 | 1.8 | 40 | 300 | 300 | Heavy GPN Observed |
| 3 | 1 | 40 | 300 | 0 | No GPN Observed |
| 4 | 1.4 | 50 | 300 | 0 | No GPN Observed |
| 5 | 1.4 | 30 | 300 | 0 | No GPN Observed |
| 6 | 1.4 | 40 | 250 | 200 | Medium GPN |
| | | | | | Observed |
| 7 | 1.4 | 40 | 350 | 0 | No GPN Observed |
| 8 | 1.5 | 40 | 300 | 0 | No GPN Observed |
| 9 | 1.6 | 40 | 300 | 320 | Heavy GPN Observed |
| 10 | 1.7 | 40 | 300 | 200 | Medium GPN |
| | | | | | Observed |
| 11 | 1.4 | 30 | 350 | 0 | No GPN Observed |
| 12 | 1.4 | 50 | 250 | 300 | Heavy GPN Observed |

As is relevant to the above discussion and approaches for depositing Tungsten on a Ti/TiN layer, the concentration of SiF₄ and SiHF₃ during Tungsten CVD reactions varies depending on the flow ratios of reactants. Different concentrations of SiF₄/SiHF₃ are detected and used as indicators of a gas phase nucleation condition. Using these indicators, the flow of gas to the deposition process is controlled and used to mitigate the reaction of Fluorine and exposed Titanium.

FIG. 2 is a flow diagram for nucleation-controlled semiconductor wafer manufacture, according to another example embodiment of the present invention. The approach shown in FIG. 2 can be implemented using a system such as the system 100 in FIG. 1, or a different system for carrying out controlled deposition.

At block 210, reaction gas characteristics are detected using an optical detection approach. The detected characteristics are processed at block 220 to determine a condition of gas phase nucleation, which is used as an indicator of the onset of undesirable metal-gas interactions. If gas phase nucleation is detected at block 230, the composition of gases supplied for deposition is controlled to mitigate metal-gas interactions (as relevant, e.g., to the mitigation of gas phase nucleation). If gas phase nucleation is not detected at block 230, or after detection and control at block 240, the process continues at block 210 to continually monitor the deposition process until it is complete.

FIG. 3A and FIG. 3B respectively show plots 300 and 305 of reaction gas characteristics used to detect gas phase nucleation and control material deposition in accordance with one or more example embodiments of the present invention. The plots correspond to an example Tungsten deposition process, relating to Equations 1 and 2 above, in which peaks are detected for SiF₄ and WF₆ and used as an indication of gas phase nucleation.

Beginning with FIG. 3A, a set of five peaks are shown, with the set of middle three peaks labeled for each of SiF₄ and WF₆. The first (leftmost) peak is from a pre-coat process, the labeled middle three peaks represent actual deposition (three peaks correspond to three measurements), and the last (rightmost) peak is from vent step. During the deposition process, the intensity of the SiF₄ peaks 310, 320 and 330 is higher than the intensity of the WF₆ peaks 340, 350 and 360. Since SiF₄ is the by-product of the chemical reaction, an increase of SiF₄ is used as an indicator of gas phase nucleation and the deposition process is controlled accordingly. For instance, as described above, a microprocessor or other controller can use data indicative of the onset of gas phase nucleation to control the deposition process to mitigate or avoid conditions relating to gas phase nucleation.

In FIG. 3B, a similar set of five peaks are shown, with the middle three peaks also labeled for each of SiF₄ and WF₆, and the leftmost and rightmost peaks corresponding respectively to a pre-coat process and a vent step. The SiF₄ peaks 312, 322 and 332 are about the same high as the WF₆ peaks 342, 352 and 362, thus exhibiting similar intensity. This similar intensity is used as an indicator that gas phase nucleation is not occurring.

Using the detection approaches shown in FIG. 3A and in FIG. 3B, steps can be taken to ensure undesirable conditions are addressed, such as by controlling the supply of gas and/or the timing of deposition.

FIG. 4 shows a graphical approach 400 to detecting gas phase nucleation, according to another example embodiment of the present invention. The bar graphs respectively show example intensity-based test results obtained under different processing times and/or conditions. These results are monitored and used as an indicator of gas phase nucleation conditions, and are implemented during deposition processes for mitigating undesirable conditions related to gas phase nucleation. As the intensity shown by the bar graphs drops toward a negative value (e.g., over time during monitoring), the drop is used as an indicator of gas phase nucleation.

In accordance with another example embodiment, an empirical judgment criteria approach is implemented as follows for determining gas phase nucleation:

If (WF₆—SiF₄)>−15:No GPN if (WF₆—SiF₄)<−15: GPN (3)

The presence of WF₆ and SiF₄ is detected and used with Equation 3 as follows. If the difference WF₆-SiF₄ is greater than −15 (negative 15), a determination is made that gas phase nucleation is not occurring. If the difference WF₆-SiF₄ is less than −15, gas phase nucleation is detected. Using Equation 3 with a controller and microcomputer, manually or otherwise, gas phase nucleation conditions are detected and a deposition process from which data is collected is controlled accordingly.

The various embodiments described above and shown in the figures are provided by way of illustration only and should not be construed to limit the invention. Based on the above discussion and illustrations, those skilled in the art will readily recognize that various modifications and changes may be made to the present invention without strictly following the exemplary embodiments and applications illustrated and described herein. For example, different types of optical spectrometers or other detectors may be used in addition to and/or in place of the described IR spectrometers, and the described IR spectrometers may be used in a variety of different arrangements. In addition, the indicated approaches are applicable to a variety of processes and deposition approaches, such as CVD as described above, variants of CVD (e.g., low pressure CVD (LPCVD)), and other deposition approaches. Such modifications and changes do not depart from the true scope of the present invention.

1. A method for nucleation-controlled semiconductor device manufacture, the method comprising:
introducing reactant gases to a substrate and reacting the gases to form metal on the substrate;
optically detecting by-product gases created by reactions between the reactant gases; and
controlling the introduction of reactant gases to the substrate as a function of the detected by-product gases to mitigate gas phase nucleation.

2. The method of claim 1, wherein
introducing reactant gases to a substrate includes introducing reactant gases to a substrate having exposed Titanium, and
controlling the introduction of reactant gases to the substrate as a function of the detected by-product gases includes controlling the introduction of reactant gases to mitigate reactions between gases and the exposed Titanium.

3. The method of claim 1, wherein controlling the introduction of reactant gases to the substrate as a function of the detected by-product gases includes using the detected by-product gases to determine a ratio of reactant gases, and in response to the determined ratio, controlling the introduction of reactant gases to provide a desirable ratio of reactant gases.

4. The method of claim 1, wherein
optically detecting by-product gases created by reactions between the reactant gases includes detecting an intensity of at least two by-product gases, and controlling the introduction of reactant gases to the substrate as a function of the detected by-product gases includes controlling the introduction of reactant gases in response to a difference between the intensities of the two by-product gases.

5. The method of claim 1, wherein controlling the introduction of reactant gases to the substrate as a function of the detected by-product gases includes controlling the flow of reactant gases into a chamber to maintain a ratio of reactant gases that is below a threshold ratio that is known to promote gas phase nucleation.

6. The method of claim 1, wherein
introducing reactant gases to a substrate includes introducing reactant gases to a control environment that is separate from a deposition chamber in which the substrate is located,
optically detecting by-product gases created by reactions between the reactant gases includes optically detecting by-product gases created by reactions between the reactant gases in the control environment, and
controlling the introduction of reactant gases to the substrate as a function of the detected by-product gases to mitigate gas phase nucleation includes controlling the introduction of reactant gases to the deposition chamber using the detected by-product gases in the control environment.

7. The method of claim 1, wherein
introducing reactant gases to a substrate and reacting the gases to form metal on the substrate include introducing WF6 and SiH4 to a substrate having a TiN barrier layer on a Titanium layer to for a seed layer of Tungsten via nucleation,
optically detecting by-product gases created by reactions between the reactant gases includes optically detecting by-product gases during the nucleation of the Tungsten, and
controlling the introduction of reactant gases to the substrate as a function of the detected by-product gases to mitigate gas phase nucleation includes controlling the introduction of WF6 and SiH4.

8. The method of claim 1, wherein,
optically detecting by-product gases created by reactions between the reactant gases includes optically detecting the reactant gases, and
controlling the introduction of reactant gases to the substrate as a function of the detected by-product gases to mitigate gas phase nucleation includes controlling the introduction of reactant gases to the substrate as a function of the detected by-product gases and reactant gases.

9. A method for nucleation-controlled growth of a Tungsten layer on a Ti/TiN substrate, the method comprising:
using a gas flow controller, introducing WF6 and SiH4 reactant gases to a substrate having a TiN barrier layer on a Titanium layer and reacting the reactant gases to form a Tungsten seed layer on the TiN barrier layer, and;
while reacting the reactant gases, optically detecting by-product gases created by reactions between the reactant gases and providing an output indicative of an intensity of the detected gases;
using the intensity output, providing feedback control to the gas flow controller to control the introduction of the reactant gases to the substrate to mitigate gas phase nucleation, and to mitigate reactions between WF6 and the Titanium that form TiF3.

10. The method of claim 9, wherein
optically detecting by-product gases created by reactions between the reactant gases includes detecting intensity values of the by-product gases and providing an intensity output indicative of the intensity of the by-product gases, and
providing feedback control includes using the intensity output to determine a ratio of gases at the substrate and providing feedback control in response to the determined ratio.

11. The method of claim 9, wherein
providing feedback control includes using the intensity output to determine a ratio of reactant gases controlling the gas flow controller to control the introduction of reactant gases to maintain the intensity ratio at a value that is below a threshold ratio value that is known to promote gas phase nucleation.

12. A system for nucleation-controlled semiconductor device manufacture, the system comprising:
a gas supply arrangement to introduce reactant gases to a substrate for reacting the gases to form metal on the substrate;
an optical detector arrangement to optically detect by-product gases created by reactions between the reactant gases and to provide a signal indicative of the detected gases; and
a controller to control the gas supply arrangement to introduce reactant gases to the substrate as a function of the detected by-product gas signal to mitigate gas phase nucleation.

13. The system of claim 12, wherein the controller controls the gas supply arrangement to mitigate reactions between gases and an exposed metal layer on the substrate.

14. The system of claim 12, wherein the controller is programmed to use the detected by-product gas signal to determine a ratio of gases, and controls the gas supply arrangement in response to the determined ratio of gases.

15. The system of claim 12, wherein the optical detector is an infrared spectrometer.

16. The system of claim 12, wherein the controller sends a control signal to the gas supply arrangement using a feedback loop to actively control the gas supply during formation of the metal on the substrate.

17. The system of claim 12, wherein
the gas supply arrangement introduces WF6 and SiH4 reactant gases to a substrate having a TiN barrier layer on a Titanium layer to react the reactant gases and form a Tungsten seed layer on the TiN barrier layer and,
the controller provides a feedback signal to control the gas supply for introducing reactant gases to the substrate to mitigate reactions between WF6 and the Titanium that form TiF3.

18. The system of claim 12, wherein
the optical detector detects intensity values that are indicative of the amount of each reactant gas present, and
the controller monitors a ratio of the respective intensities of the reactant gases and controls the gas supply in response to the monitored ratio.

19. The system of claim 12, wherein the gas supply arrangement, optical detector and controller are integrated into a common manufacturing tool that implements data interpretation software to process the detected by-product gas signal and to provide a feedback control signal for controlling the supply of reactant gases in response thereto.
